(19) United States
(12) Patent Application Publication
(10) Pub. No.: US 2012/0182698 A1
(43) Pub. Date: Jul. 19, 2012

(54) ASSEMBLY FOR INSTALLING BUILDING SYSTEMS ENGINEERING UNITS

(76) Inventors: Hans-Joachim Langels, Langquaid (DE); Alexander Mauer, Regensburg (DE); Rainer Sedmeier, Regensburg (DE)

(21) Appl. No.: 13/498,848

(22) PCT Filed: Aug. 12, 2010
(86) PCT No.: PCT/EP2010/061738

§ 371 Date: Mar. 28, 2012

(30) Foreign Application Priority Data
Sep. 29, 2009 (DE) 10 2009 043 455.0

(51) Int. Cl. H05K 7/00

(52) U.S. Cl. 361/728

(57) ABSTRACT

An assembly for installing building systems engineering units includes a housing, which comprises a control device for carrying out an electronic function, and a base module which is designed for fastening the housing for a pre-determined installation situation. The housing and the base module are designed for fixed but removable connection so that the housing can be connected to a base module adapted to the respective installation situation in dependence on the installation situation. The modular sub-division of an installation unit into a base module and a housing, which comprises the control device for carrying out a defined function, can significantly reduce the diversity of variants.

### CROSS-REFERENCE TO RELATED APPLICATIONS

This application is a U.S. National Stage Application of International Application No. PCT/EP2010/061738 filed Aug. 12, 2010, which designates the United States of America, and claims priority to DE Patent Application No. 10 2009 043 455.0 filed Sep. 29, 2009. The contents of which are hereby incorporated by reference in their entirety.

### TECHNICAL FIELD

This disclosure relates to an assembly for installing building automation devices.

### BACKGROUND

In many building automation systems, installation devices, for example actuators and sensors, are installed in buildings. The installation devices used here differ essentially with regard to their function and installation situation, i.e., the way in which they are fitted. For example, pushbuttons, motion detectors, regulators or display and control units are fitted in different installation situations, such as recessed, surface-mounted, beneath raised floors or above suspended ceilings, in regard to their respective function, for instance switching, dimming, temperature measurement or controlling sunscreens. Different types of construction and methods of fitting exist for these different functions and installation situations, often requiring a large number of product variants. For a manufacturer of such electrical installation devices, this may mean a high level of complexity in production and manufacturing logistics and correspondingly higher production costs. A large number of variants may also involves correspondingly complex and costly stock-keeping for both the manufacturer of electrical installation devices and for installation companies carrying out the installation work.

### SUMMARY

In one embodiment, an assembly for installing building automation devices includes a housing, which contains a control device for performing an electronic function, and a base module, which is designed for fastening the housing for a predetermined installation situation, wherein the housing and the base module are designed to provide a firm but detachable connection, so that, depending on the installation situation, the housing can be connected to a base module adapted to the specific installation situation.

In a further embodiment, the housing contains a control device for temperature control and/or lighting control and/or sunscreen control and/or fire prevention monitoring and/or burglary prevention. In a further embodiment, the base module is designed to receive a plurality of housings. In a further embodiment, the housing and the base module are connected together via an interface which is designed to transmit electrical signals and/or to supply electrical power. In a further embodiment, the base module can be connected to a bus system, so that a connection between the control device and the bus system can be realized via the interface. In a further embodiment, the control device is connected to a control module to enable user-operation of the control device. In a further embodiment, the base module contains the control module, with the control module being connected to the control device via an interface of the base module.

In a further embodiment, the control device is connected to an extra control module, which enables additional user-operation of the control device. In a further embodiment, the base module is designed for recessed mounting or surface mounting. In a further embodiment, the base module is designed as a closeable installation box, said installation box comprising a bus connecting line for connecting to a bus system, via which line the base module can be connected to the bus system. In a further embodiment, the installation box comprises a top-hat rail for mounting DIN-rail mounted devices, with the base module also being mounted on the top-hat rail. In a further embodiment, the top-hat rail contains a data rail via which the base module communicates with the bus system. In a further embodiment, the bus connecting line is designed to supply power to the base module. In a further embodiment, the power is supplied by means of a local supply disposed in the installation box. In a further embodiment, an additional installation box can be connected to the installation box via the bus connecting line.

### BRIEF DESCRIPTION OF THE DRAWINGS

Example embodiments will be explained in more detail below with reference to figures, in which:

FIGS. 1a to 1d show schematic diagrams of an assembly according to example embodiments,

FIG. 2 shows a schematic diagram of an example assembly having a connected control module, according to an example embodiment,

FIGS. 3a to 3c show schematic diagrams of example alternative embodiments of a base module designed as an installation box, and

FIGS. 4a to 4d show schematic diagrams of example alternative power supply options for the installation box.

### DETAILED DESCRIPTION

Some embodiments provide an assembly for installing building automation devices that are characterized by a lower number of product variants.

Some embodiments provide an assembly for installing building automation devices that comprises a housing, which contains a control device for performing an electronic function. In addition, the assembly may comprise a base module, which is designed for fastening the housing for a predetermined installation situation. The housing and the base module may be designed to provide a firm but detachable connection, so that, depending on the installation situation, the housing can be connected to a base module adapted to the specific installation situation.

The range of variants can be reduced significantly by modularizing an installation device into a base module and a housing that contains the control device for performing a defined function. The base module is used to achieve adaptation to the specific installation situation, for instance recessed or surface-mounted installation or installation in installation boxes. The control device disposed in the housing is used to achieve adaptation to the function to be implemented. The facility to combine different control devices with different base modules means that far fewer individual components are needed to implement the different requirements as regards function and installation situation. This means that a fitter can personally assemble the next installation device that is needed from a manageable number of base modules and housings containing control device, for example by plugging together the components in question. The fitter can hence configure the base module and housing according to the specific application. This may significantly simplify development, production, logistics and/or installation.

In an example embodiment of the assembly, the housing contains a control device for temperature control and/or lighting control and/or sunscreen control and/or fire prevention monitoring and/or burglary prevention.

The stated alternatives are common controller functions from the building automation sector and are listed here by way of example. It is also possible, however, to equip the housing with a control device for performing a function other than the stated functions.

In a further embodiment of the assembly, the base module is designed to receive a plurality of housings.

This may provide the advantage that shared functionalities that are made available to the plurality of housings only need to be provided once in the base module. Fastening means for the specific installation situation is one example of a shared functionality.

Likewise, other functionalities that are used by a plurality of housings can be provided in common in the base unit. This applies both to housings containing control devices having the same functionality and to housings containing control devices having a different functionality. For the assembly to work, however, it is not necessary that a plurality of housings are connected to the base module. It is equally possible that only one housing is connected to the base module, with there being the facility to receive additional housings. Furthermore, it is possible to allow placement of only certain housings and to block placement of other housings by coding, e.g. mechanically coding, certain positions on the base module that are designed to receive a housing. This makes it possible to combine a defined function only with one or a plurality of defined installation situations and to block one or a plurality of defined installation situations for the function in question.

In a further embodiment of the assembly, the housing and the base module are connected together via an interface which is designed to transmit electrical signals and/or to supply electrical power.

If the base module is connected to a power supply, then the control device disposed in the housing can also be supplied with power via the interface. It may be advantageous to dispose all the hardware and software components required for performing the relevant function of the control device in the housing. Shared functionalities can be disposed in the base module. Communication between the base module and the housing or more particularly the control device can also be implemented via the interface.

In a further embodiment of the assembly, the base module can be connected to a bus system, so that a connection between the control device and the bus system can be realized via the interface.

A processor in the base module is not essential in order to connect the base module to the bus system; if the processor technology required for bus communication is integrated in each housing connected to the base module, it is sufficient for the base module to have a simple bus connection terminal in order to implement communication between the control device and the bus system. By connecting the housing to the base module, it is automatically detected by means of the control device whether the assembly is intended to be used as a bus device or as an electronic module, i.e. whether the base module is connected to a bus system or whether it is operated independently of a bus system. If the assembly is connected to a bus system, the power supply for communication between the control device and the bus system can be provided via the bus line. Alternatively, it is equally possible to use a local power supply.

In a further embodiment of the assembly, the control device is connected to a control module to enable user-operation of the control device.

A user can easily transmit control commands to the control device by means of the control module. The control module may be, for instance, a pushbutton, a dimmer or some other operator control. Since different control modules are needed to implement some of the different functions, these control modules have a defined, standardized interface so that they can be combined in a modular manner with the particular base module or the particular control device of the assembly. Thus it is not essential to define the particular combination in the factory; it is also possible for the combination forming the particular assembly, comprising base module, control device and control module, to be made not until installation of the building installation devices by a fitter on site.

In a further embodiment of the assembly, the base module contains the control module, with the control module being connected to the control device via an interface of the base module.

For ease of use of the assembly, it can be advantageous to connect the control module to the base module rather than directly to the control device. In this case, the control device is operated via the control module and the interface between the base module and the control device.

In a further embodiment of the assembly, the control device is connected to an extra control module, which enables additional user-operation of the control device.

The extra control module can be used to implement an extension function. This means that the control device can be operated not just from one control module but from a plurality of control modules. The interface for connecting the control modules either to the base module or to the control device is designed in this case so that additional extension inputs can be added to it if required. The customer can thereby be provided automatically with extensions for implementing the required functionality without needing to install additional base modules or control devices for this purpose.

In a further embodiment of the assembly, the base module is designed for recessed mounting or surface mounting.

Recessed or surface-mounted installation are two possible ways of implementing common methods of fitting. Unlike surface-mounted installation, in which the base module and the housing containing the control device are mounted on the wall in question, with recessed installation, a box embedded in the wall is provided (known as a flush-fitting wall box), into which the base module is fitted together with the housing of the control device. The box can then be closed by a protective lid, for example. Alternatively, the box can also be closed by a control module plugged onto the base module or the housing.

In a further embodiment of the assembly, the base module is designed as a closeable installation box, said installation box comprising a bus connecting line for connecting to a bus system, via which line the base module can be connected to the bus system.

Using an installation box is another method of fitting. In this case, the installation box is intended for mounting in the ceiling or floor, i.e. the installation box is installed beneath raised floors or above suspended ceilings. Unlike recessed installation, in which the assembly is installed in a flush-fitting wall box, the installation box is larger and designed to be closeable. This provides a protective function, for example to protect against electric shock, moisture, dust or other environmental influences, and also protects the installation box against unauthorized access.

In a further embodiment of the assembly, the installation box comprises a top-hat rail for mounting DIN-rail mounted devices, with the base module also being mounted on the top-hat rail.

A top-hat rail is a roll-formed metal mounting-rail with U-shaped cross-section that is used for mounting components in distribution boxes or junction boxes. DIN-rail mounted devices to be installed, for example circuit breakers or miniature circuit breakers, can be mounted on the top-hat rail by snap-fitting or sliding onto the rail, for example, thereby simplifying installation considerably. Straightforward and quick installation of the base module in the installation box can be achieved by designing the base module so that it can also be mounted or snap-fitted on a top-hat rail.

In a further embodiment of the assembly, the top-hat rail contains a data rail via which the base module communicates with the bus system.

The data rail may be designed, for example, as a printed circuit board that has a variety of contact-making facilities and is inserted in the U-section top-hat rail. The terminals for communication between the base module and the bus system are electrically connected to the contact-making facilities on the printed circuit board via the underside of the base module by clipping or snap-fitting the base module onto the top-hat rail. This further simplifies installation of the base module.

In a further embodiment of the assembly, the bus connecting line is designed to supply power to the base module.

A separate power line can be dispensed with by using the bus connecting line to supply power to the base module. This may further simplify installation of the base module.

In a further embodiment of the assembly, the power is supplied by means of a local supply disposed in the installation box.

A local power supply may be advantageous, for example, when the amount of power required in the installation box exceeds the amount of power available via the bus connecting line. The local supply can be designed as a modular power supply module that can be installed easily in the installation box by plugging it onto a predefined interface.

As a means of adapting to the power consumption of the devices fitted in the installation box, it is possible to provide a plurality of slots in the installation box for local power supply modules of this type. It is obviously likewise possible to use a power supply module of this type in addition to the power supply via the bus connecting line.

In a further embodiment of the assembly, an additional installation box can be connected to the installation box via the bus connecting line.

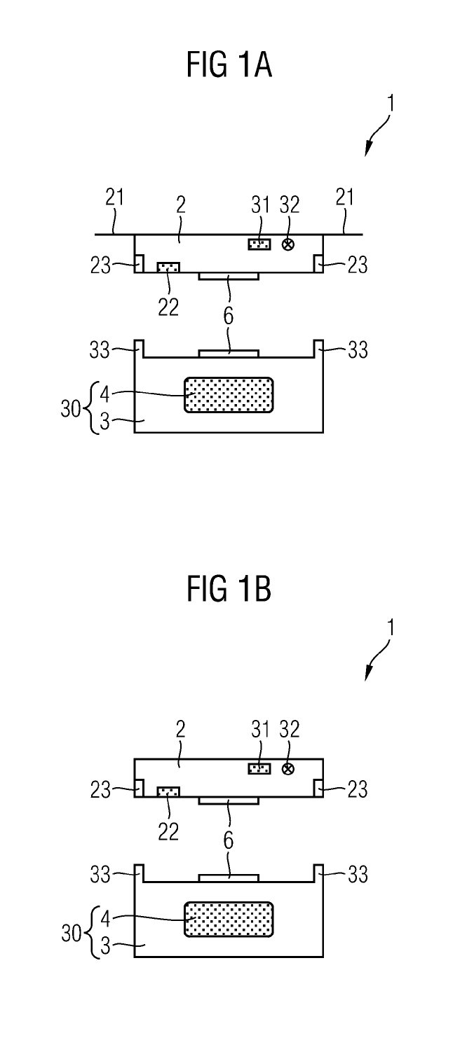

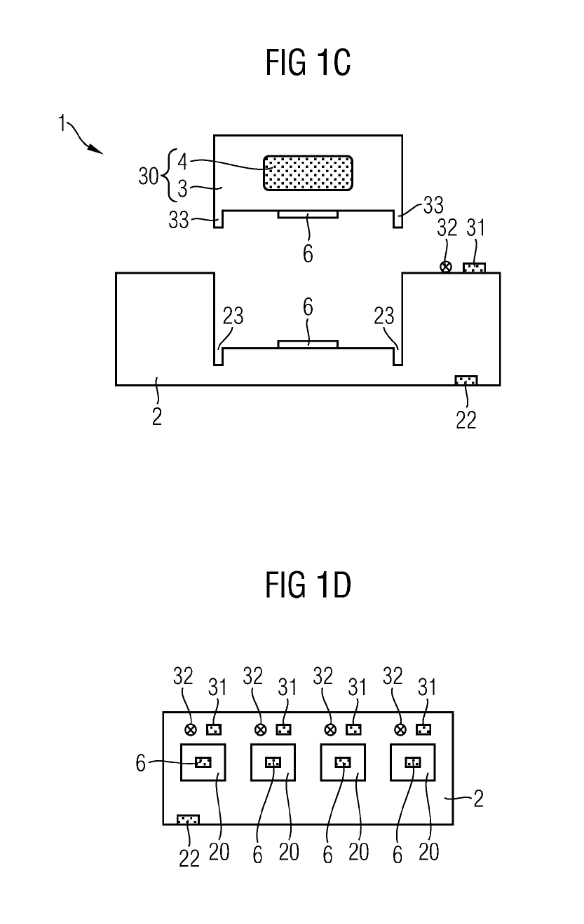

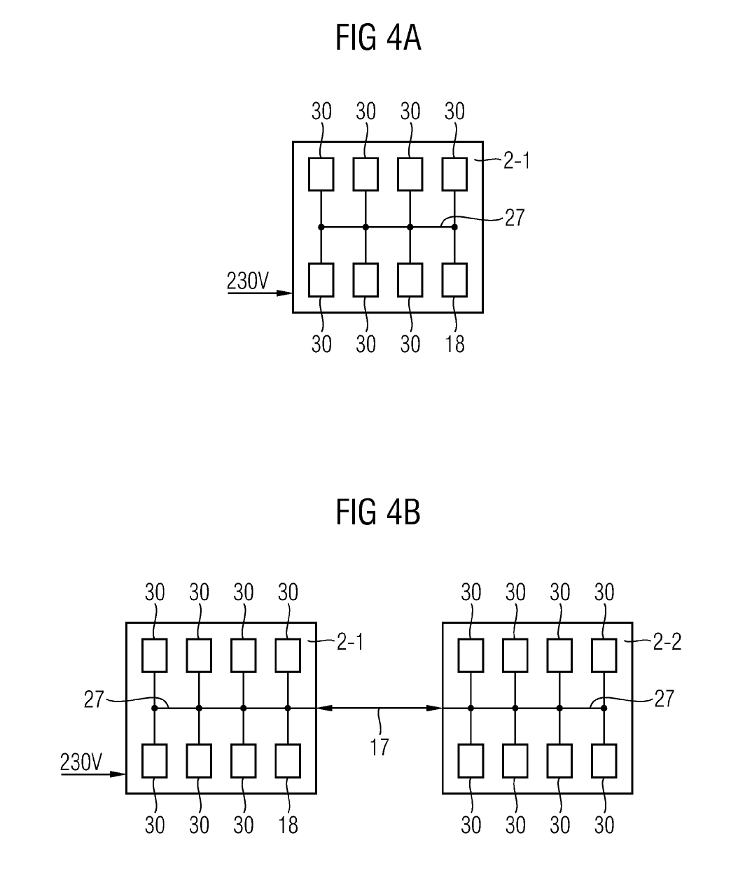

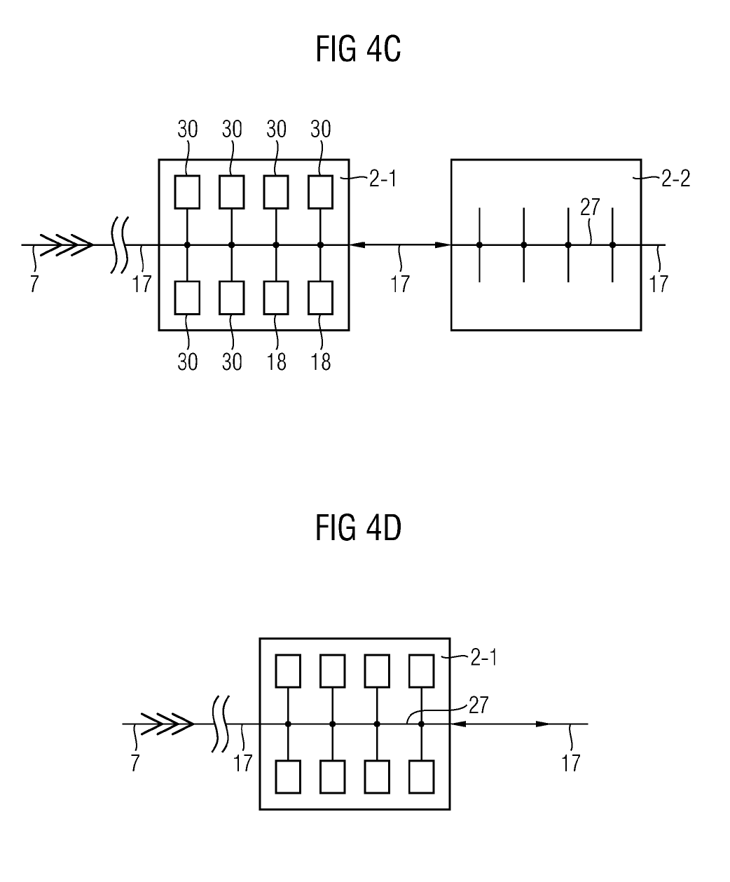

It is possible to vary the number of slots available for installing installation devices for the building automation system by connecting an additional installation box via the bus connecting line. In this case, it is possible to supply power also to the devices in the second connected installation box via the bus connecting line. It is also possible, however, to provide a local power supply module in at least one of the two connected installation boxes in order to supply power to the installation devices installed in this installation box. FIGS. 1a to 1d show schematically the fundamental design of the assembly 1 according to example embodiments. This design uses a specific base module 2 for each different method of fitting. For example, FIGS. 1a and 1b each show an embodiment of the assembly 1 in which the base module 2 is designed for recessed installation with (FIG. 1a) or without (FIG. 1b) mounting bracket 21. In contrast, base module 2 shown in FIG. 1c is intended for surface-mounted installation. In each case, the base module 2 has a bus connection terminal 22, via which a connection to a bus system (see FIGS. 4a to 4d) can be made. An additional component of the assembly 1 is a housing 3, which contains a control device 4 for performing a defined function, for example controlling lighting, temperature or blinds. Such a housing 3 containing the control device 4 is usually called a sensor/actuator module 30. For each different function there is a specific control device 4, and hence a specific sensor/actuator module 30, which may comprises all the hardware and firmware components needed to perform the specific function. These components will likely include a communications module in addition to function hardware and a processor. A defined set of hardware functions that are required for a plurality of sensor/actuator modules 30 can also be provided via the base module 2. In this regard, the base module 2 has in each of the diagrams of FIGS. 1a to 1d a programming button 31 and an associated programming LED 32. The programming button 31 is provided for a fitter or commissioning engineer to configure the set of functions for the sensor/actuator module 30, with said programming LED 32 displaying a respective programming status. If there is sufficient installation space, in principle it is also possible to dispose the programming button 31 and the associated programming button 32 directly on the sensor/actuator module 30.

Both the base module 2 and the sensor/actuator module 30 have an interface 6 via which data can be transferred between the control device 4 and the base module 2. The interface 6 can be designed as a SAMI interface (Sensor Actuator Module Interface). In addition to serving as an adapter for the specific installation situation, the base module 2 can also be used to provide various hardware functions for the sensor/actuator module 30 connected to the base module 2. For example, the control device 4 can be connected to a bus system 7 via the SAMI interface 6 and the bus connection terminal 22 formed on the base module 2 (see FIGS. 4a to 4d). The base module 2 does not have a processor capability of its own, however, but merely acts as a bus connector for the sensor/actuator module 30. The sensor/actuator module 30 can also be supplied with electrical power via the base module 2 and the interface 6. In addition, for independent addressing and programming of the sensor/actuator module 30, the interface 6 provides the facility for identifying the sensor/actuator module 30 and for indicating whether the sensor/actuator module 30 is in programming mode; this is indicated by the programming LED 32.

In addition to the data communications interface 6, there is also a mechanical interface between the base module 2 and the housing 3 that is used to fasten the housing 3 securely to the base module 2. In the diagrams in FIGS. 1a to 1c, in each case two legs 33 are formed on the housing 3 for this purpose that engage in corresponding locating holes 23 formed in the base module 2. This plug-in connection is just one possible embodiment of the mechanical interface. Alternatively, other embodiments can also be used, for example a hinge-catch connection employing a hinge that has a catch facility and is arranged between base module 2 and housing 3.

FIG. 1d shows a base module 2 comprising a plurality of slots 20, each having an associated interface 6, for receiving and connecting a plurality of sensor/actuator modules 30. Such a base module 2 can be provided both for surface-mounted and recessed installation.

The assembly 1, i.e., both the various base modules 2 and the various sensor/actuator modules 30, may be designed such that it can be configured by a user, for example by a fitter, for a specific application. The overall size is designed so that a sensor/actuator module 30 can also be inserted in a base module 2 embodied as a conventional flush-fitting wall box. In addition, it is possible to remove a sensor/actuator module 30 from one base module 2 and combine it with another base module 2 without making changes to the firmware or the configuration, so that it is possible, for example, to implement the same function using a different method of fitting.

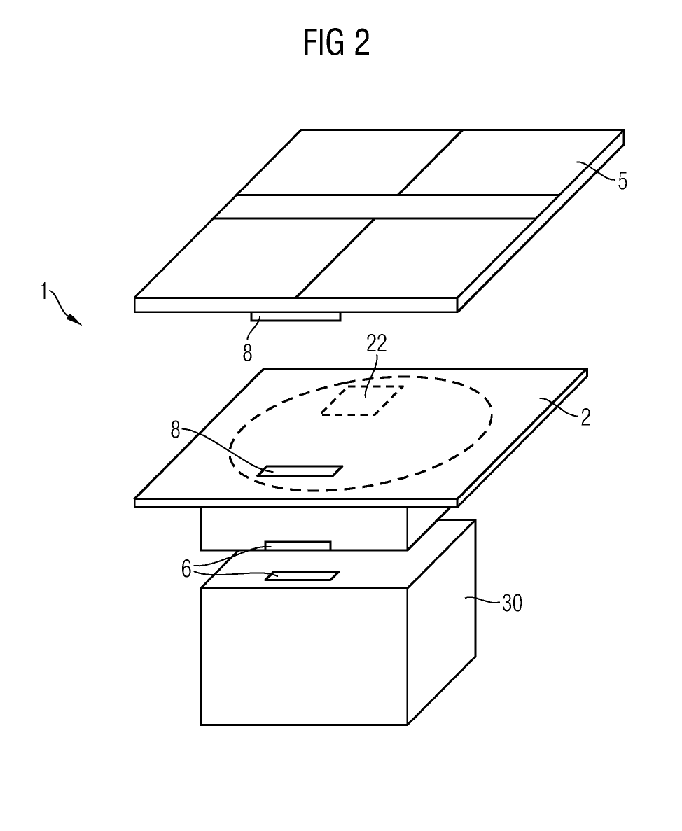

FIG. 2 shows schematically the assembly 1 according to an example embodiment having a control module 5 connected thereto. Once again, the assembly 1 essentially comprises the base module 2, to which the sensor/actuator module 30 can be connected via the interface 6. In this case, the base module 2 again has a bus connection terminal 22 (see FIG. 1) for connecting the assembly 1 to a bus system 7. In addition, the base module 2 comprises an additional interface 8, via which the control module 5 can be connected to the base module 2. The control module 5 may be a pushbutton, for example.

The control module 5 communicates with the sensor/actuator module 30 via the additional interface 8 and the interface 6. The bus protocol is advantageously used for this communication. A sensor/actuator module 30 connected to the base module 2 can thereby be operated by means of bus communication by a control module 5 plugged onto the base module 2. Here, the assembly 1, i.e. the combination of a specific base module 2 with a specific sensor/actuator module 30, can be configured by the user. Since the sensor/actuator module 30 has a dedicated processor having application-specific firmware and a dedicated bus address, it can be configured independently of the control module 5. It is no longer necessary to adapt or modify firmware in the control module 5 or configure the control module 5 specifically for the currently assigned sensor/actuator module 30 connected to the base module 2.

In addition, the assembly 1 shown makes it possible to configure a function, which is to be implemented using the control device 4 of the sensor/actuator module 30, irrespective of whether or not a control module 5 is already connected thereto. Thus a range of different configuration options, i.e. combinations with different base modules 2 and/or different control modules 5 are available for each newly developed sensor/actuator module 30 without additional complexity.

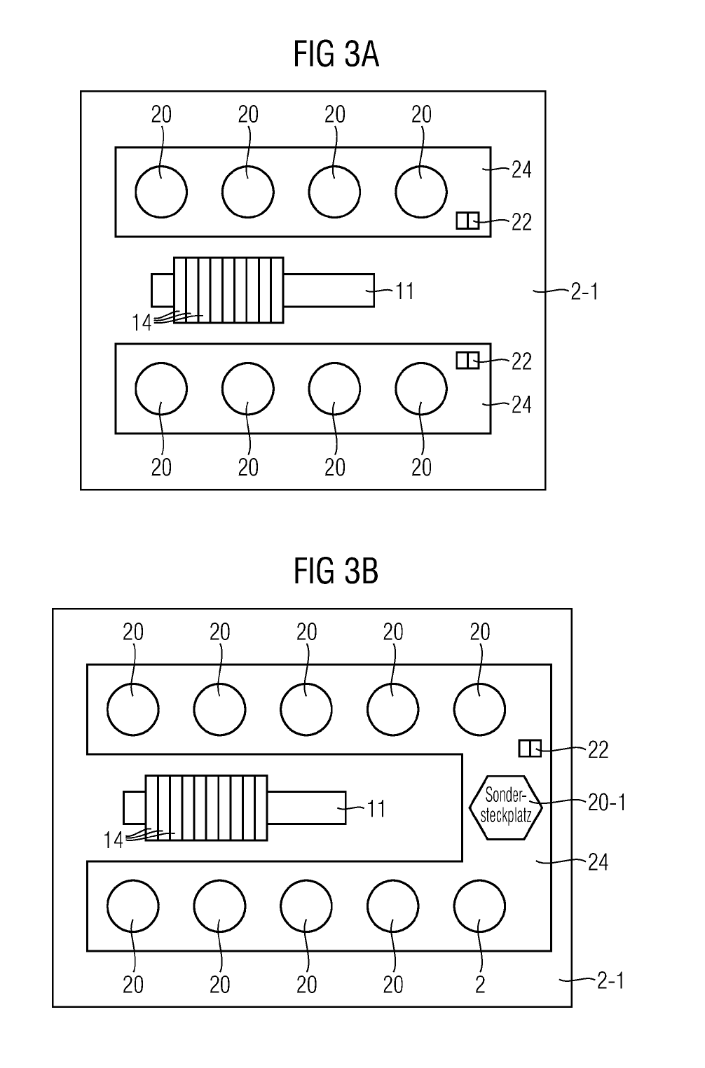

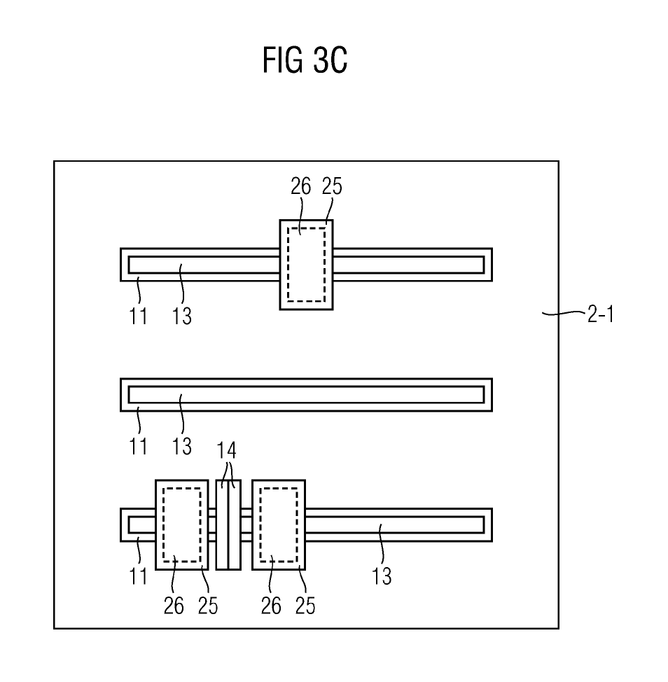

FIGS. 3a to 3c show schematically different embodiments of a base module 2 designed as an installation box 2-1. Using an installation box 2-1 is another method of fitting. The installation box 2-1 is usually provided for installation in a ceiling or floor, i.e. the installation box 2-1 is installed beneath raised floors or above suspended ceilings. The installation box 2-1 can also be installed in a wall, however. The installation box 2-1 provides a protective function, for example protecting against electric shock, moisture, dust or other environmental influences. It is also possible for the installation box 2-1 to have a closeable design in order to provide protection against unauthorized access.

Inside the installation box 2-1 shown in FIGS. 3a and 3b is a top-hat rail 11. This is a roll-formed metal mounting-rail onto which are clipped the DIN-rail mounted terminals 14 for connecting incoming lines and/or for internal wiring. In addition, the installation box 2-1 comprises two mounting plates 24, each of which are provided with a plurality of slots 20 for connecting sensor/actuator modules 30. The mounting plates 24 each additionally comprise a bus connection terminal 22, by means of which a communications connection between the currently connected sensor/actuator modules 30 and a bus system 7 can be achieved (see FIGS. 4a to 4d). Since the control device 4 of each sensor/actuator module 30 already comprises a processor and a communications module, a central processor is not needed to control the installation box 2-1.

For the assembly 1 to work, it is not necessary to connect a sensor/actuator module 30 to all the slots 20. It is equally possible to populate only some of the slots 20 with said modules. The slots 20 have a standardized design and can be used to connect different sensor/actuator modules 30 and special module types. Mechanical coding can be used, however, to allow only certain modules to be connected to specific slots 20.

The power supply for communication can be provided here via the bus system 7 and the bus connection terminals 22. It is also possible, however, to reserve one of the slots 20 for a local power supply 18 (see FIGS. 4a to 4d). In addition, one of the slots 20 can also be used for connecting an IP router in order to enable the installation box 2-1 to access alternative networks, for instance IP networks or LAN networks. Furthermore, one of the slots 20 can also be used by a coupling unit in order to connect another installation box 2-2 (see FIGS. 4a to 4d). Alternatively, there is the option to integrate special module types such as IP routers, coupling units, local power supply 18 or programming interfaces directly in the installation box 2-1, for instance in the mounting plate 24 using a special slot 20-1, so that all the other slots 20 are available for connecting sensor/actuator modules 30.

The installation box 2-1 shown in FIG. 3c differs from this arrangement in that it comprises a plurality of top-hat rails 11, which are designed both for attaching DIN-rail mounted terminals 14 or DIN-rail mounted devices and for connecting sensor/actuator modules 30. A data rail 13 is inserted in the top-hat rails, via which it is possible to communicate with the bus system 7. A top-hat rail adapter 25 is used to connect a sensor/actuator module 30. This adapter comprises a backplane printed circuit board 26 that provides the interface 6 for each connected sensor/actuator module 30 and provides communication with the bus system 7 via the data rail 13. Top-hat rail adapter 25 and backplane printed circuit board 26 have a standardized design. They can be used for connecting a sensor/actuator module 30 and a special module such as a coupling unit, IP routers, a local power supply 18 or a programming interface.

FIGS. 4a to 4d show schematically alternative power supply options for the installation box 2-1, according to example embodiments.

In FIG. 4a, the installation box 2-1 is used in isolated operation, i.e. autonomously. The connected sensor/actuator modules 30 are connected together for data communication by an internal bus system 27. The internal bus system 27 is supplied with power via a local powers supply 18, which is connected to an external power supply. The local power supply 18 is connected to one of the slots 20 and is supplied via an external power line, for instance a 230V domestic supply line. It is also possible, however, to integrate the local power supply 18 permanently in the installation box 2-1.

In FIG. 4b, an additional installation box 2-2 is connected to the first installation box 2-1 via a bus connecting line 17. Both installation boxes 2-1 and 2-2 have an internal bus system 27 and are again operated autonomously, in isolation from their surroundings. The first installation box 2-1 again comprises a local power supply 18 for supplying power to the sensor/actuator modules 30 disposed therein. The sensor/actuator modules 30 connected in the additional installation box 2-2 can also be supplied with power, however, via the bus connecting line 17, so that an additional local power supply is not essential. If required, however, additional local power supply modules 18 can be connected to one of the available slots 20 of one of the two installation boxes 2-1 and/or 2-2.

The installation boxes 2-1 and 2-2 shown in FIGS. 4c and 4d differ from this arrangement in that they are not operated autonomously, but are connected to an external bus system 7 via a bus connecting line 17. In this case, this is a bus system 7 that has a central bus power supply, i.e. the first installation box 2-1 is supplied with power from the central power supply via the bus connecting line 17. The additional installation box 2-2 is also supplied with power via the extension bus connecting line 17 between the installation boxes 2-1 and 2-2. Likewise, additional appended installation boxes can be supplied with power via additional extension bus connecting lines 17. If required, this central bus power supply can be augmented or boosted by local power supply modules 18, it also being possible to have a plurality of local power supply modules 18 in one installation box.

The installation boxes 2-1 and 2-2 shown in FIGS. 3 and 4 can be populated with the various DIN-rail mounted devices from the widest range of manufacturers by means of the top-hat rails 11 disposed therein. Depending on the application, the top-hat rail 11 can be disposed in different positions in the installation box. For particularly low-profile installation boxes, it is also possible to fit the DIN-rail mounted devices so that they lie flat in the installation box. In this case, the top-hat rail is rotated through 90° in the installation box. The most diverse range of designs for partitioning the space inside the installation box 2-1 can hence be realized depending on the requirement.

### LIST OF ELEMENTS SHOWN IN THE DRAWINGS

1 assembly
2 base module
2-1 installation box
2-2 additional installation box
3 housing
4 control device
5 control module
6 interface/SAMI interface
7 bus system
8 interface
11 top-hat rail
12 DIN-rail mounted device
13 data rail
14 DIN-rail mounted terminal
17 bus connecting line
18 local power supply unit/power supply
20 slot
20-1 special slot
21 mounting bracket
22 bus terminal
23 locating hole
24 mounting plate
25 top-hat rail adapter
26 backplane printed circuit board
27 internal bus system
30 actuator/sensor module
31 programming button
32 programming LED
33 leg

What is claimed is:

1. An assembly for installing building automation devices, comprising:
a housing for a control device for performing an electronic function,
a base module configured to fasten the housing for a predetermined installation situation,
wherein the housing and the base module provide a firm but detachable connection, so that, the housing can be adaptively connected to the base module in various different installation situations.

2. The assembly of claim 1, wherein the a control device is configured for at least one of: temperature control, lighting control, sunscreen control, fire prevention monitoring, and burglary prevention.

3. The assembly of claim, wherein the base module is configured to receive a plurality of housings.

4. The assembly of claim 1, wherein the housing and the base module are connected together via an interface configured to transmit electrical signals or supply electrical power.

5. The assembly of claim 4, wherein the base module is connected to a bus system such that a connection between the control device and the bus system is realized via the interface.

6. The assembly of claim 1, wherein the control device is connected to a control module to enable user-operation of the control device.

7. The assembly of claim 6, wherein the base module contains the control module, with the control module being connected to the control device via an interface of the base module.

8. The assembly of claim 1, wherein the control device is connected to an extra control module, which enables additional user-operation of the control device.

9. The assembly of claim 1, wherein the base module is configured for recessed mounting or surface mounting.

10. The assembly claim 1, wherein the base module is configured as a closeable installation box, said installation box comprising a bus connecting line for connecting to a bus system, via which line the base module is connectable to the bus system.

11. The assembly of claim 10, wherein the installation box comprises a top-hat rail for mounting DIN-rail mounted devices, with the base module also being mounted on the top-hat rail.

12. The assembly of claim 11, wherein the top-hat rail contains a data rail via which the base module communicates with the bus system.

13. The assembly of claim 10, wherein the bus connecting line is configured to supply power to the base module.

14. The assembly of claim 13, wherein the power is supplied by means of a local supply disposed in the installation box.

15. The assembly of claim 10, wherein an additional installation box is connected to the installation box via the bus connecting line.
